(19) United States
(12) Patent Application Publication
(10) Pub. No.: US 2026/0013112 A1
(43) Pub. Date: Jan. 8, 2026

(54) SEMICONDUCTOR STRUCTURE WITH RECESS TRANSISTORS AND METHOD OF MANUFACTURING THE SAME

(71) Applicant: NANYA TECHNOLOGY CORPORATION, NEW TAIPEI CITY (TW)

(72) Inventor: PING HSU, New Taipei City (TW)

(21) Appl. No.: 18/761,803

(22) Filed: Jul. 2, 2024

(51) Int. Cl. H10B 12/00

(52) U.S. Cl. CPC H10B 12/34; H10B 12/0335; H10B 12/488

(57) ABSTRACT

The present application provides a semiconductor structure and a method of manufacturing the same. The semiconductor structure includes a device and at least one recess transistor. The device includes a substrate and a plurality of word lines. The substrate includes an array portion and a periphery portion surrounding the array portion. The plurality of word lines are disposed in the array portion. The periphery portion is free of word lines. The periphery portion of the substrate defines at least one recess. The at least one recess transistor is disposed in the at least one recess of the periphery portion of the substrate.

### TECHNICAL FIELD

The present disclosure relates to a semiconductor structure and a method of manufacturing the same, and more particularly, to a semiconductor structure including a recess transistor, and a method of manufacturing the same.

### DISCUSSION OF THE BACKGROUND

Semiconductor structures are used in various electronic applications, including personal computers, cellular telephones, digital cameras, and other electronic equipment. Sizes of semiconductor devices are continuously decreasing to meet the growing demand for computing power. However, such scaling down presents challenges that are becoming more frequent and impactful. Therefore, there are still challenges to overcome in improving quality, yield, performance and reliability while reducing complexity.

A typical memory device (such as a dynamic random-access (DRAM) device) includes signal lines, such as word lines and bit lines crossing the word lines. As DRAM devices are scaled down and dimensions and/or pitches of signal lines are getting smaller, challenges of current leakage control of DRAM devices have arisen.

This Discussion of the Background section is provided for background information only. The statements in this Discussion of the Background are not an admission that the subject matter disclosed in this Discussion of the Background section constitute prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor structure. The semiconductor structure includes a device and at least one recess transistor. The device includes a substrate and a plurality of word lines. The substrate includes an array portion and a periphery portion surrounding the array portion. The plurality of word lines are disposed in the array portion. The periphery portion of the substrate defines at least one trench. The at least one recess transistor is disposed in the at least one trench of the periphery portion of the substrate.

One aspect of the present disclosure provides a semiconductor structure. The semiconductor structure includes a device, at least one recess transistor and at least one shallow trench isolation (STI). The device includes a substrate with an array portion and a periphery portion surrounding the array portion, and a plurality of word lines disposed in the array portion, wherein the periphery portion is free of word lines, and wherein the periphery portion defines at least one recess. The at least one recess transistor is disposed in the at least one recess of the periphery portion of the substrate, wherein the at least one recess transistor includes a plurality of recess transistors with different widths. The at least one shallow trench isolation (STI) is disposed between each recess transistor and an adjacent recess transistor.

Another aspect of the present disclosure provides a method of manufacturing a semiconductor structure. The method includes providing a device, wherein the device includes a substrate and a plurality of word lines, wherein the substrate comprises an array portion and a periphery portion surrounding the array portion, the plurality of word lines are disposed in the array portion, and the periphery portion is free of word lines; forming at least one trench in the periphery portion of the substrate; and forming at least one recess transistor in the at least one trench of the periphery portion of the substrate.

Another aspect of the present disclosure provides a method of manufacturing a semiconductor structure. The method includes providing a substrate having a first surface and a second surface opposite to the first surface; concavely forming a trench on the first surface of the substrate; forming a plurality of liners positioned on side surfaces of the trench; and forming a first insulating segment filling the trench.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures' reference numbers, which refer to similar elements throughout the description.

FIG. 1A is a cross-sectional view of a semiconductor structure in accordance with some embodiments of the present disclosure.

FIG. 1B is a cross-sectional view of a semiconductor structure in accordance with some embodiments of the present disclosure.

FIG. 2A is a cross-sectional view of a semiconductor structure in accordance with some embodiments of the present disclosure.

FIG. 2B is a cross-sectional view of a semiconductor structure in accordance with some embodiments of the present disclosure.

FIG. 3 is a cross-sectional view of one or more stages of an example of a method of manufacturing a semiconductor structure in accordance with some embodiments of the present disclosure.

FIG. 4 is a cross-sectional view of one or more stages of an example of a method of manufacturing a semiconductor structure in accordance with some embodiments of the present disclosure.

FIG. 5 is a cross-sectional view of one or more stages of an example of a method of manufacturing a semiconductor structure in accordance with some embodiments of the present disclosure.

FIG. 6 is a cross-sectional view of one or more stages of an example of a method of manufacturing a semiconductor structure in accordance with some embodiments of the present disclosure.

FIG. 7 is a cross-sectional view of one or more stages of an example of a method of manufacturing a semiconductor structure in accordance with some embodiments of the present disclosure.

FIG. 8 is a cross-sectional view of one or more stages of an example of a method of manufacturing a semiconductor structure in accordance with some embodiments of the present disclosure.

FIG. 9 is a cross-sectional view of one or more stages of an example of a method of manufacturing a semiconductor structure in accordance with some embodiments of the present disclosure.

FIG. 10 is a cross-sectional view of one or more stages of an example of a method of manufacturing a semiconductor structure in accordance with some embodiments of the present disclosure.

FIG. 11 is a cross-sectional view of one or more stages of an example of a method of manufacturing a semiconductor structure in accordance with some embodiments of the present disclosure.

FIG. 12 is a cross-sectional view of one or more stages of an example of a method of manufacturing a semiconductor structure in accordance with some embodiments of the present disclosure.

FIG. 13 is a cross-sectional view of one or more stages of an example of a method of manufacturing a semiconductor structure in accordance with some embodiments of the present disclosure.

FIG. 14 is a cross-sectional view of one or more stages of an example of a method of manufacturing a semiconductor structure in accordance with some embodiments of the present disclosure.

FIG. 15 is a cross-sectional view of one or more stages of an example of a method of manufacturing a semiconductor structure in accordance with some embodiments of the present disclosure.

FIG. 16 is a cross-sectional view of one or more stages of an example of a method of manufacturing a semiconductor structure in accordance with some embodiments of the present disclosure.

FIG. 17 is a cross-sectional view of one or more stages of an example of a method of manufacturing a semiconductor structure in accordance with some embodiments of the present disclosure.

FIG. 18 is a cross-sectional view of one or more stages of an example of a method of manufacturing a semiconductor structure in accordance with some embodiments of the present disclosure.

FIG. 19 is a cross-sectional view of one or more stages of an example of a method of manufacturing a semiconductor structure in accordance with some embodiments of the present disclosure.

FIG. 20 is a cross-sectional view of one or more stages of an example of a method of manufacturing a semiconductor structure in accordance with some embodiments of the present disclosure.

FIG. 21 is a cross-sectional view of one or more stages of an example of a method of manufacturing a semiconductor structure in accordance with some embodiments of the present disclosure.

FIG. 22 is a cross-sectional view of one or more stages of an example of a method of manufacturing a semiconductor structure in accordance with some embodiments of the present disclosure.

FIG. 23 is a cross-sectional view of one or more stages of an example of a method of manufacturing a semiconductor structure in accordance with some embodiments of the present disclosure.

FIG. 24 is a flowchart of a method of manufacturing a semiconductor structure in accordance with some embodiments of the present disclosure.

### DETAILED DESCRIPTION

Embodiments, or examples, of the disclosure illustrated in the drawings are now described using a specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It should be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It should be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

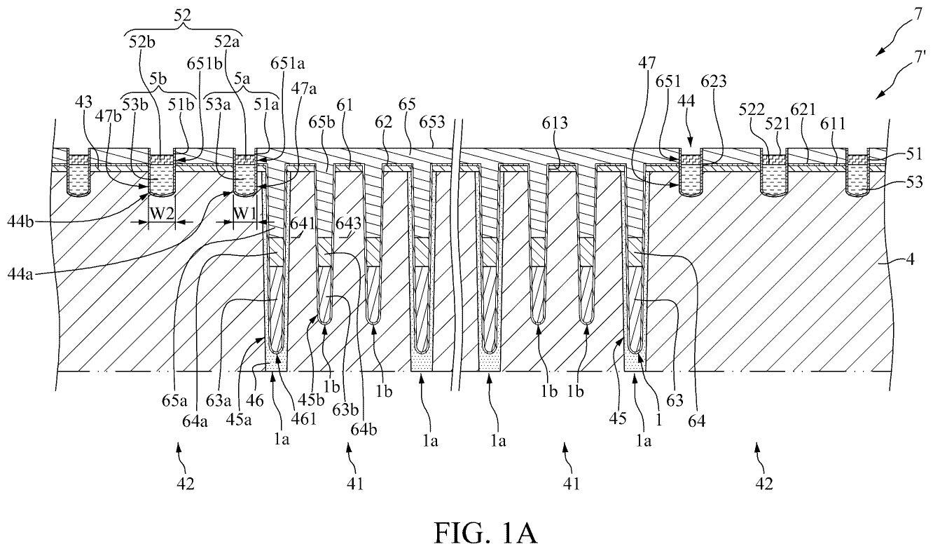

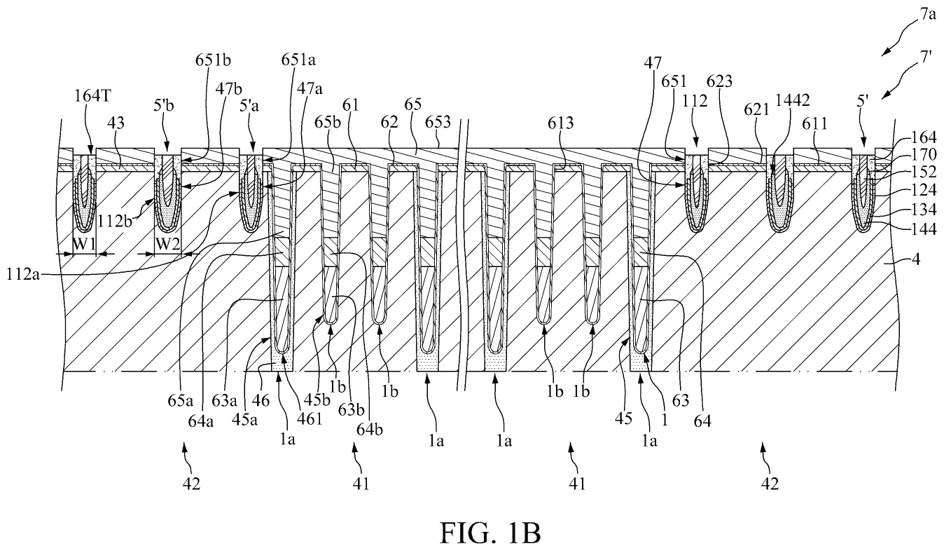

FIG. 1A is a cross-sectional view of a semiconductor structure 7 in accordance with some embodiments of the present disclosure. In some embodiments, the semiconductor structure 7 may be a semiconductor device that includes a circuit, such as a memory cell. In some embodiments, the memory cell may include a dynamic random-access memory cell (DRAM cell).

In addition, the semiconductor structure 7 may be or include a portion of an integrated circuit (IC) chip that includes various passive and active microelectronic devices, such as resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, fin field-effect transistors (FinFETs), other suitable IC components, or combinations thereof.

The semiconductor structure 7 may include a device 7′ and at least one recess transistor 5. The device 7′ may include a substrate 4, a plurality of word lines 1, a cover layer 61, an isolation layer 62, a conductive material 63, a polysilicon layer 64 and a word line nitride layer 65. The substrate 4 may include, for example, silicon (Si), germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials.

In some embodiments, as shown in FIG. 1A, the substrate 4 may have a first surface 43 (e.g., a top surface). The substrate 4 may include an array portion 41 (or an array region) and a periphery portion 42 (or a periphery region) surrounding the array portion 41. The word lines 1 are disposed in the array portion 41, and the periphery portion 42 is free of word lines 1. In other words, the array portion 41 includes all of the word lines 1 that may be arranged in an array. The periphery portion 42 includes no word lines 1. The periphery portion 42 may be a region that is outside the distribution region of the word lines 1.

The substrate 4 may define a plurality of trenches 45 and at least one recess 47. The trenches 45 and the at least one recess 47 are recessed into the first surface 43 of the substrate 4. The trenches 45 may be located within the array portion 41. The recess 47 may be located in the periphery portion 42, and located outside the array portion 41. Thus, the array portion 41 of the substrate 4 may define the trenches 45, and the periphery portion 42 of the substrate 4 may define the recess 47.

The trenches 45 may include a plurality of first trenches 45a and a plurality of second trenches 45b. A depth of the first trench 45a may be greater than a depth of the second trench 45b. An isolation material 46 may be disposed in the first trench 45a, and may define an accommodation trench 461. In some embodiments, the isolation material 46 may include, for example, oxide, and may be embedded in the substrate 4.

The cover layer 61 may be disposed on and may cover the first surface 43 of the substrate 4. In some embodiments, the cover layer 61 may include, for example, nitride. The cover layer 61 may have a first surface 611 (e.g., a top surface). The cover layer 61 may define a plurality of openings 613 to expose the second trench 45b, the accommodation trench 461 and the at least one recess 47.

The isolation layer 62 may be disposed on and may cover the first surface 611 of the cover layer 61. In some embodiments, the isolation layer 62 may include, for example, oxide. The isolation layer 62 may have a first surface 621 (e.g., a top surface). The isolation layer 62 may define a plurality of openings 623 to expose the at least one recess 47. In addition, the isolation layer 62 may extend into the second trench 45b and the accommodation trench 461. Thus, the isolation layer 62 may be disposed on a sidewall of the second trench 45b and a sidewall of the accommodation trench 461.

In some embodiments, the conductive material 63 may be, for example, a metal material. The metal material may include, for example, tungsten. The conductive material 63 may include a first conductive material 63a and a second conductive material 63b. The first conductive material 63a may be disposed on the isolation layer 62 in the accommodation trench 461. The second conductive material 63b may be disposed on the isolation layer 62 in the second trench 45b.

In some embodiments, the polysilicon layer 64 may include a first polysilicon layer 64a and a second polysilicon layer 64b. The first polysilicon layer 64a may be disposed on the first conductive material 63a in the accommodation trench 461. The second polysilicon layer 64b may be disposed on the second conductive material 63b in the second trench 45b. In some embodiments, as shown in FIG. 1A, a thickness of the first polysilicon layer 64a may be substantially equal to a thickness of the second polysilicon layer 64b. An elevation 641 of the first polysilicon layer 64a may be same as an elevation 643 of the second polysilicon layer 64b. In some embodiments, the thickness of the first polysilicon layer 64a may be less than a thickness of the first conductive material 63a. The thickness of the second polysilicon layer 64b may be less than a thickness of the second conductive material 63b.

The word line nitride layer 65 may be disposed on and may cover the first surface 621 of the isolation layer 62. Thus, the word line nitride layer 65 may cover the array portion 41 and the periphery portion 42 (e.g., the first surface 43 of the substrate 4). The word line nitride layer 65 may have a first surface 653 (e.g., a top surface). The word line nitride layer 65 may define a plurality of openings 651 to expose the at least one recess 47. In addition, the word line nitride layer 65 may extend into the second trench 45b and the accommodation trench 461. In some embodiments, a first portion 65a of the word line nitride layer 65 may extend into the accommodation trench 461 to contact the first polysilicon layer 64a. A second portion 65b of the word line nitride layer 65 may extend into the second trench 45b to contact the second polysilicon layer 64b.

As shown in FIG. 1A, the word lines 1 may include a plurality of first word lines 1a and a plurality of second word lines 1b. The first word lines 1a may be disposed in the accommodation trench 461, and may include the first conductive material 63a, the first polysilicon layer 64a and the first portion 65a of the word line nitride layer 65. The second word lines 1b may be disposed in the second trench 45b, and may include the second conductive material 63b, the second polysilicon layer 64b and the second portion 65b of the word line nitride layer 65. The word line nitride layer 65 may extend into the word lines 1. In some embodiments, the first portion 65a of the word line nitride layer 65 may extend into the first word line 1a. The second portion 65b of the word line nitride layer 65 may extend into the second word line 1b.

The at least one recess 47 of the periphery portion 42 of the substrate 4 may include a plurality of recesses 47. As shown in FIG. 1A, the recesses 47 may include at least one first recess 47a and at least one second recess 47b. A width W1 of the first recess 47a may be different from a width W2 of the second recess 47b. In some embodiments, the width W1 of the first recess 47a may be less than the width W2 of the second recess 47b.

In addition, the word line nitride layer 65 may define at least one opening 651 corresponding to the at least one recess 47 of the periphery portion 42. The opening 651 may extend through the word line nitride layer 65, and may include a first opening 651a and a second opening 651b. The first opening 651a may correspond to the first recess 47a, and the second opening 651b may correspond to the second recess 47b. In some embodiments, the opening 651 of the word line nitride layer 65, the recess 47 of the periphery portion 42, the opening 613 of the cover layer 61 and the opening 623 of the isolation layer 62 may collectively form at least one outer trench 44 recessed into the first surface 653 of the word line nitride layer 65. The outer trench 44 may include a first outer trench 44a and a second outer trench 44b. In some embodiments, the first opening 651a, the first recess 47a, the opening 613 of the cover layer 61 and the opening 623 of the isolation layer 62 may collectively form the first outer trench 44a recessed into the first surface 653 of the word line nitride layer 65. In addition, the second opening 651b, the second recess 47b, the opening 613 of the cover layer 61 and the opening 623 of the isolation layer 62 may collectively form the second outer trench 44b recessed into the first surface 653 of the word line nitride layer 65.

The recess transistor 5 may be disposed in the outer trench 44. In some embodiments, the recess transistor 5 may be disposed in the periphery portion 42 of the substrate 4. The recess transistor 5 may include an insulation layer 51, a polysilicon layer 53 and a gate conductor 52. The insulation layer 51 may be disposed on a sidewall of the outer trench 44. The polysilicon layer 53 may be disposed on the insulation layer 51 in the recess 47 of the periphery portion 42 of the substrate 4. Thus, the insulation layer 51 may be disposed between the polysilicon layer 53 and the periphery portion 42 of the substrate 4. The gate conductor 52 may be disposed on the polysilicon layer 53 and the insulation layer 51. Thus, the gate conductor 52 may be disposed in the opening 651 of the word line nitride layer 65. The insulation layer 51 may be disposed between the gate conductor 52 and the word line nitride layer 65. Therefore, the recess transistor 5 may be disposed in the recess 47 of the periphery portion 42 of the substrate 4 and in the opening 651 of the word line nitride layer 65.

As shown in FIG. 1A, a bottom surface 522 of the gate conductor 52 may be higher than the first surface 43 (e.g., the top surface) of the substrate 4. In some embodiments, the bottom surface 522 of the gate conductor 52 may be higher than the first surface 611 (e.g., the top surface) of the cover layer 61. The bottom surface 522 of the gate conductor 52 may be lower than the first surface 621 (e.g., the top surface) of the isolation layer 62. In addition, a top surface 521 of the gate conductor 52 may be lower than the first surface 653 (e.g., the top surface) of the word line nitride layer 65, and may be higher than the first surface 621 (e.g., the top surface) of the isolation layer 62.

In some embodiments, the insulation layer 51 may include a first insulation layer 51a and a second insulation layer 51b. The polysilicon layer 53 may include a first polysilicon layer 53a and a second polysilicon layer 53b. The gate conductor 52 may include a first gate conductor 52a and a second gate conductor 52b. The first insulation layer 51a may be disposed on a sidewall of the first outer trench 44a. The first polysilicon layer 53a may be disposed on the first insulation layer 51a in the first recess 47a of the periphery portion 42 of the substrate 4. Thus, the first insulation layer 51a may be disposed between the first polysilicon layer 53a and the periphery portion 42 of the substrate 4. The first gate conductor 52a may be disposed on the first polysilicon layer 53a and the first insulation layer 51a. Thus, the first gate conductor 52a may be disposed in the first opening 651a of the word line nitride layer 65. The first insulation layer 51a may be disposed between the first gate conductor 52a and the word line nitride layer 65. The first insulation layer 51a, the first polysilicon layer 53a and the first gate conductor 52a may collectively form a first recess transistor 5a. The first recess transistor 5a may be disposed in the first outer trench 44a, and may have a width W1.

The second insulation layer 51b may be disposed on a sidewall of the second outer trench 44b. The second polysilicon layer 53b may be disposed on the second insulation layer 51b in the second recess 47b of the periphery portion 42 of the substrate 4. Thus, the second insulation layer 51b may be disposed between the second polysilicon layer 53b and the periphery portion 42 of the substrate 4. The second gate conductor 52b may be disposed on the second polysilicon layer 53b and the second insulation layer 51b. Thus, the second gate conductor 52b may be disposed in the second opening 651b of the word line nitride layer 65. The second insulation layer 51b may be disposed between the second gate conductor 52b and the word line nitride layer 65. The second insulation layer 51b, the second polysilicon layer 53b and the second gate conductor 52b may collectively form a second recess transistor 5b. The second recess transistor 5b may be disposed in the second outer trench 44b, and may have a width W2. Therefore, the recess transistor 5 may include a plurality of recess transistors 5a, 5b with different widths W1, W2.

In the embodiment illustrated in FIG. 1A, the recess transistor 5 (including, for example, the first recess transistor 5a and the second recess transistor 5b) is recessed into the first surface 653 (e.g., the top surface) of the word line nitride layer 65, thus, a size (e.g., a thickness) of the semiconductor structure 7 may be reduced. In addition, the recess transistor 5 (including, for example, the first recess transistor 5a and the second recess transistor 5b) can mitigate a leakage issue, since a channel length of the recess transistor 5 (including, for example, the first recess transistor 5a and the second recess transistor 5b) is relatively long. In addition, the widths W1, W2 of the recess transistor 5 (including, for example, the first recess transistor 5a and the second recess transistor 5b) may be reduced.

FIG. 1B is a cross-sectional view of a semiconductor structure 7a in accordance with some embodiments of the present disclosure. The semiconductor structure 7a in FIG. 1B is similar to the semiconductor structure 7 illustrated in FIG. 1A, except that the semiconductor structure 7a in FIG. 1B may include a recess transistor 5′ instead of the recess transistor 5 of the semiconductor structure 7 in FIG. 1A. The recess transistor 5′ may be disposed in a trench 112, wherein the trench 112 includes a first trench 112a and a second trench 112b. The recess transistor 5′ disposed in the trench 112a may be referred to as a recess transistor 5′a, while the recess transistor 5′ disposed in the trench 112b may be referred to as a recess transistor 5′b. In some embodiments, the recess transistor 5′ may be disposed in the periphery portion 42 of the substrate 4.

Referring to FIG. 1B, the recess transistor 5′ may include a conductive layer 144, an insulative plug 152, an insulation layer 124, a diffusion barrier liner 134, a gate conductor 164 and a void 170. The conductive layer 144 may be disposed in the trench 112 and surrounded by the insulation layer 124. The insulative plug 152 may be disposed in the trench 112, surrounded by the gate conductor 164 and extending into the conductive layer 144. The insulation layer 124, between the substrate 4 and the conductive layer 144, is employed to prevent junction leakage. The insulation layer 124 may be conformally disposed on an inner sidewall of the trench 112 and may cover a portion of the inner sidewall. The diffusion barrier liner 134 may be disposed between the insulation layer 124 and the conductive layer 144. The gate conductor 164 is conformally deposited in the trench 112 and over the conductive layer 144, the insulative plug 152, the insulation layer 124 and the diffusion barrier liner 134. Because the insulative plug 152 narrows the width of the outer trench 44, one or more voids 170, holding an ambient gas (such as air), can be formed in the gate conductor 164.

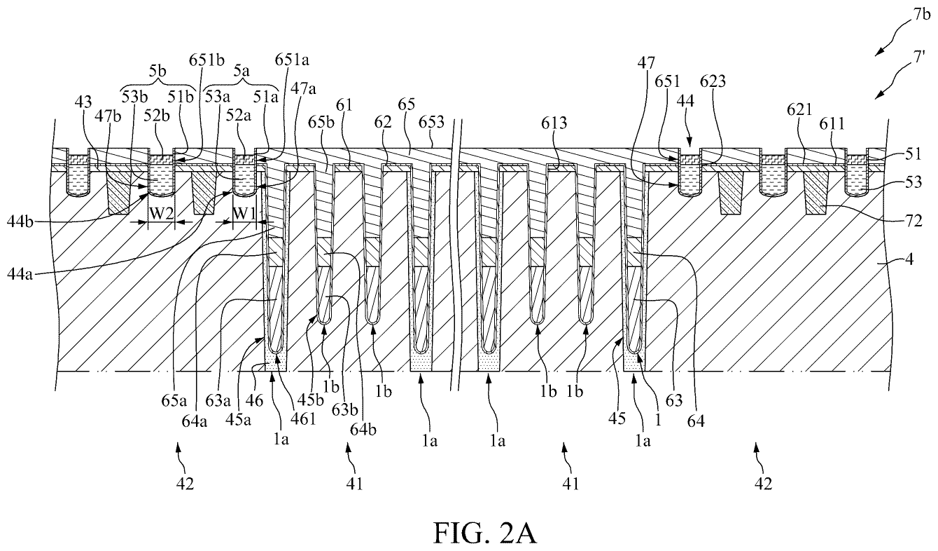

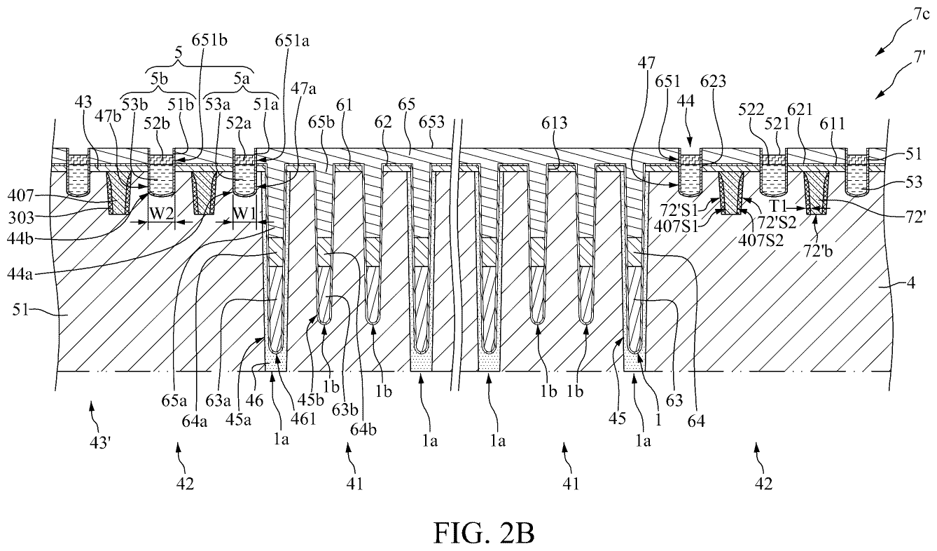

FIG. 2A is a cross-sectional view of a semiconductor structure 7b in accordance with some embodiments of the present disclosure. The semiconductor structure 7b may be similar to the semiconductor structure 7 of FIG. 1A, except that at least one shallow trench isolation (STI) 72 may be further included in the semiconductor structure 7b.

As shown in FIG. 2A, the semiconductor structure 7b further includes a plurality of the STIs 72 embedded in the substrate 4. A top surface of the STI 72 may be substantially coplanar with the first surface 43 of the substrate 4. The STI 72 may be disposed between a pair of recess transistors 5 (i.e., between the first recess transistor 5a and the second recess transistor 5b) so as to provide an isolation between the recess transistors 5.

In some embodiments, the STI 72 is formed of an insulating material, such as silicon oxide, silicon nitride, silicon oxynitride, the like, or a combination thereof. In some embodiments, the STI 72 may be formed by an STI process comprising patterning the substrate 4 by a photolithography process, etching one or more STI trenches (not shown) in the substrate 4 (e.g., by a dry etching, a wet etching, and/or a plasma etching process), and filling the STI trenches (e.g., by a chemical vapor deposition process) with one or more dielectric materials.

FIG. 2B is a cross-sectional view of a semiconductor structure 7c in accordance with some embodiments of the present disclosure. The semiconductor structure 7c in FIG. 2B is similar to the semiconductor structure 7b illustrated in FIG. 2A, except that the semiconductor structure 7c in FIG. 2B may include an STI 72′ instead of the STI 72 of the semiconductor structure 7b in FIG. 2A.

Referring to FIG. 2B, in contrast to the STI 72 in FIG. 2A, the STI 72′ further comprises a liner 303 and an insulating segment 407. The liner 303 may be disposed on side surfaces of the STI 72′. The insulating segment 407 may fill the STI 72′. Two sides of the insulating segment 407 are directly connected to the liner 303. The insulating segment 407 may cover the liner 303.

In some embodiments, a thickness T1 of the liner 303 may be between about 1.0 μm and about 10 μm. Alternatively, in another embodiment, the thickness of the liner 303 may be between about 10 nm and about 100 nm. The liner 303 may be formed of, for example, titanium, titanium nitride, titanium-tungsten alloy, tantalum, tantalum nitride, or a combination thereof. In some embodiments, a deposition process, such a CVD process, an ALD process, or the like, and an etch process, such as an anisotropic dry etch process, may be performed to form the liner 303 attached to the side surfaces of the STI 72′.

In some embodiments, the insulating segment 407 may be formed of silicon nitride, silicon oxide, silicon oxynitride, flowable oxide, tonen silazen, undoped silica glass, borosilica glass, phosphosilica glass, borophosphosilica glass, plasma-enhanced tetra-ethyl orthosilicate, fluoride silicate glass, carbon-doped silicon oxide, xerogel, aerogel, amorphous fluorinated carbon, organo silicate glass, parylene, bis-benzocyclobutenes, polyimide, porous polymeric material, or a combination thereof, but the disclosure is not limited thereto. In some embodiments, a deposition process, such as a CVD process or an ALD process, and sequentially a planarization process, such as a chemical mechanical polish process, may be performed to form the insulating segment 407 in the STI 72′.

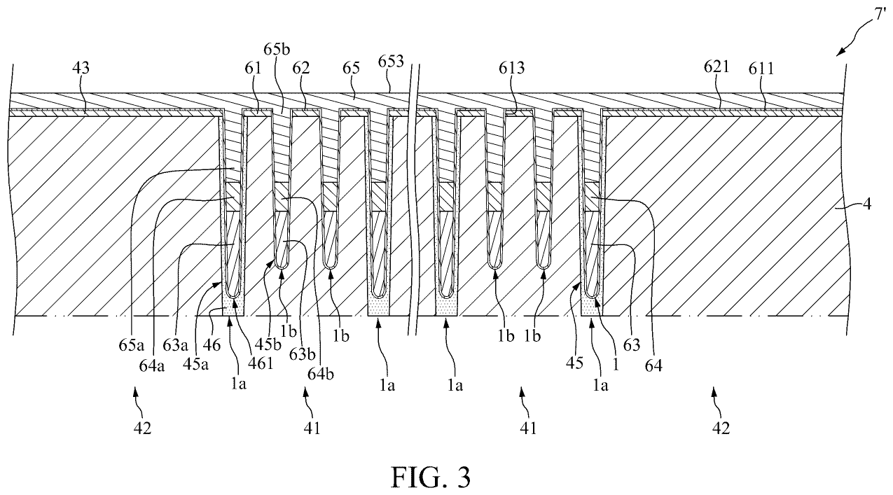

FIGS. 3 to 15 illustrate a method of manufacturing a semiconductor structure 7 according to some embodiments of the present disclosure. Referring to FIG. 3, a device 7′ is provided. The device 7′ of FIG. 3 may be same as or similar to the device 7′ of FIG. 1A.

The device 7′ may include a substrate 4, a plurality of word lines 1, a cover layer 61, an isolation layer 62, a conductive material 63, a polysilicon layer 64 and a word line nitride layer 65. The substrate 4 may include, for example, silicon (Si), germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials.

The substrate 4 may have a first surface 43 (e.g., a top surface). The substrate 4 may include an array portion 41 (or an array region) and a periphery portion 42 (or a periphery region) surrounding the array portion 41. The word lines 1 are disposed in the array portion 41, and the periphery portion 42 is free of word lines 1. That is, the array portion 41 includes all of the word lines 1 that may be arranged in an array. The periphery portion 42 includes no word lines 1. The periphery portion 42 may be a region that is outside a distribution region of the word lines 1.

The substrate 4 may define a plurality of trenches 45. The trenches 45 are recessed into the first surface 43 of the substrate 4. The trenches 45 may be located within the array portion 41. Thus, the array portion 41 of the substrate 4 may define the trenches 45. The trenches 45 may include a plurality of first trenches 45a and a plurality of second trenches 45b. A depth of the first trench 45a may be greater than a depth of the second trench 45b. An isolation material 46 may be disposed in the first trench 45a, and may define an accommodation trench 461. In some embodiments, the isolation material 46 may include, for example, oxide, and may be embedded in the substrate 4.

The cover layer 61 may be disposed on and may cover the first surface 43 of the substrate 4. In some embodiments, the cover layer 61 may include, for example, nitride. The cover layer 61 may have a first surface 611 (e.g., a top surface). The cover layer 61 may define a plurality of openings 613 to expose the second trench 45b and the accommodation trench 461.

The isolation layer 62 may be disposed on and may cover the first surface 611 of the cover layer 61. In some embodiments, the isolation layer 62 may include, for example, oxide. The isolation layer 62 may have a first surface 621 (e.g., a top surface). In addition, the isolation layer 62 may extend into the second trench 45b and the accommodation trench 461. Thus, the isolation layer 62 may be disposed on a sidewall of the second trench 45b and a sidewall of the accommodation trench 461.

In some embodiments, the conductive material 63 may be, for example, metal material. The metal material may include, for example, tungsten. The conductive material 63 may include a first conductive material 63a and a second conductive material 63b. The first conductive material 63a may be disposed on the isolation layer 62 in the accommodation trench 461. The second conductive material 63b may be disposed on the isolation layer 62 in the second trench 45b.

In some embodiments, the polysilicon layer 64 may include a first polysilicon layer 64a and a second polysilicon layer 64b. The first polysilicon layer 64a may be disposed on the first conductive material 63a in the accommodation trench 461. The second polysilicon layer 64b may be disposed on the second conductive material 63b in the second trench 45b.

The word line nitride layer 65 may be disposed on and may cover the first surface 621 of the isolation layer 62. In some embodiments, the word line nitride layer 65 may cover the array portion 41 and the periphery portion 42 (e.g., the first surface 43 (e.g., the top surface) of the substrate 4). The word line nitride layer 65 may have a first surface 653 (e.g., a top surface). In addition, the word line nitride layer 65 may extend into the second trench 45b and the accommodation trench 461. In some embodiments, a first portion 65a of the word line nitride layer 65 may extend into the accommodation trench 461 to contact the first polysilicon layer 64a. A second portion 65b of the word line nitride layer 65 may extend into the second trench 45b to contact the second polysilicon layer 64b.

As shown in FIG. 3, the word lines 1 may include a plurality of first word lines 1a and a plurality of second word lines 1b. The first word lines 1a may be disposed in the accommodation trench 461, and may include the first conductive material 63a, the first polysilicon layer 64a and the first portion 65a of the word line nitride layer 65. The second word lines 1b may be disposed in the second trench 45b, and may include the second conductive material 63b, the second polysilicon layer 64b and the second portion 65b of the word line nitride layer 65. The word line nitride layer 65 may extend into the word lines 1. In some embodiments, the first portion 65a of the word line nitride layer 65 may extend into the first word line 1a. The second portion 65b of the word line nitride layer 65 may extend into the second word line 1b.

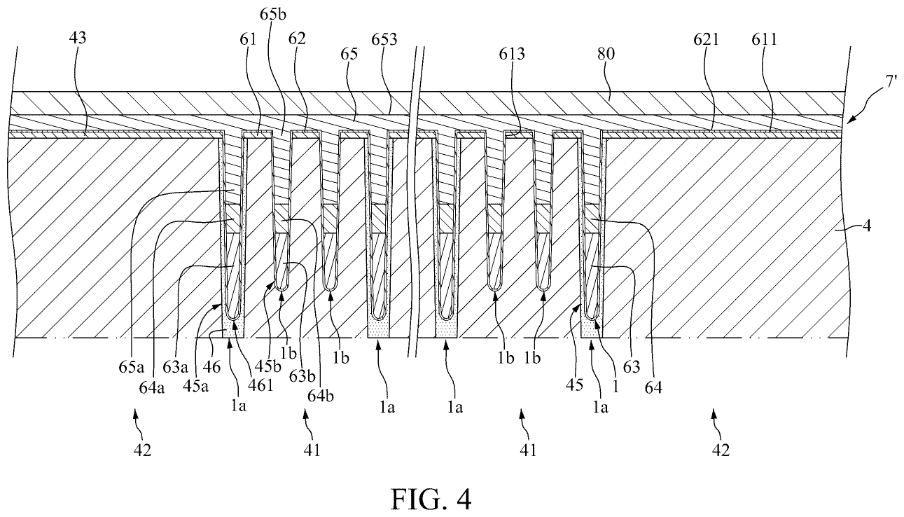

Referring to FIG. 4, a mask layer (e.g., a hard mask) 80 may be formed or disposed on the first surface 653 (e.g., the top surface) of the word line nitride layer 65 by, for example, deposition. Alternatively, the mask layer (e.g., the hard mask) 80 may be formed or disposed on the array portion 41 and the periphery portion 42 of the substrate 4.

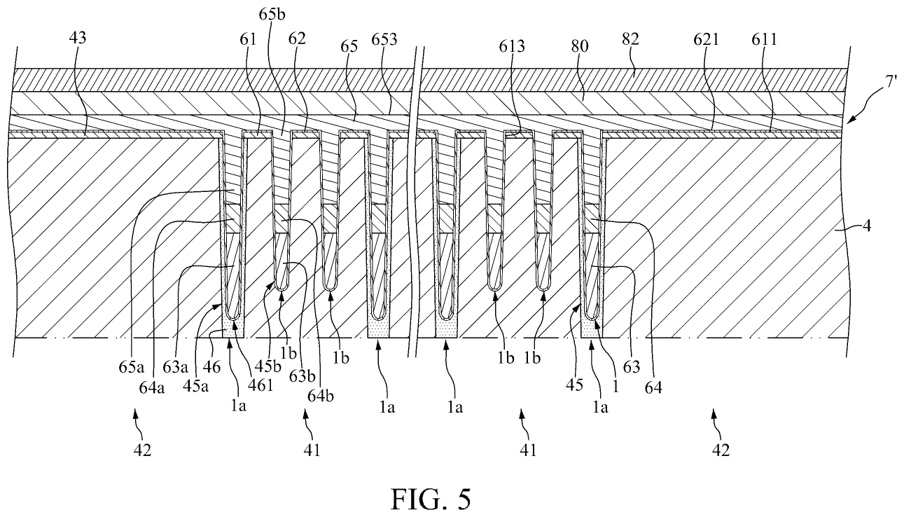

Referring to FIG. 5, a photoresist layer 82 may be formed or disposed on the mask layer 80.

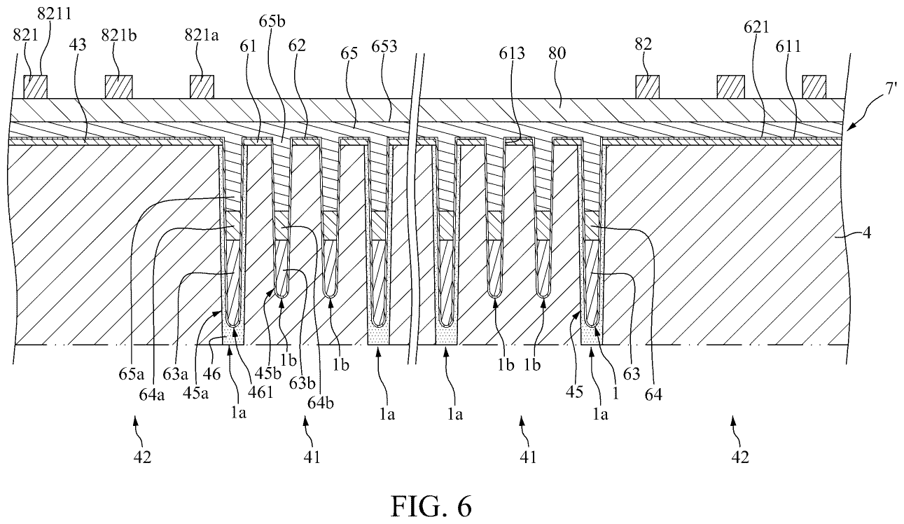

Referring to FIG. 6, the photoresist layer 82 may be patterned to include a plurality of remaining portions 821 spaced apart from each other. In some embodiments, the remaining portions 821 may include a first remaining portion 821a and a second remaining portion 821b spaced apart from each other. In some embodiments, the remaining portions 821 may be trimmed. Each of the remaining portions 821 may have a top surface 8211.

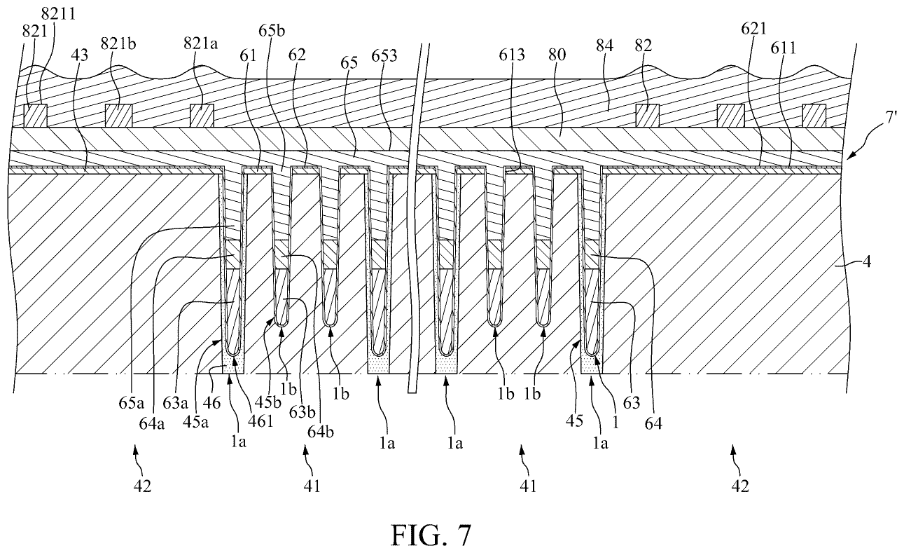

Referring to FIG. 7, a sacrificial layer 84 may be formed or disposed on the mask layer 80 to cover the remaining portions 821 of the patterned photoresist layer 82. The sacrificial layer 84 may include oxide, and may be formed by, for example, deposition. In some embodiments, a thickness of the sacrificial layer 84 may be greater than a thickness of the patterned photoresist layer 82. Thus, the sacrificial layer 84 may cover a plurality of the top surfaces 8211 of the remaining portions 821 of the patterned photoresist layer 82.

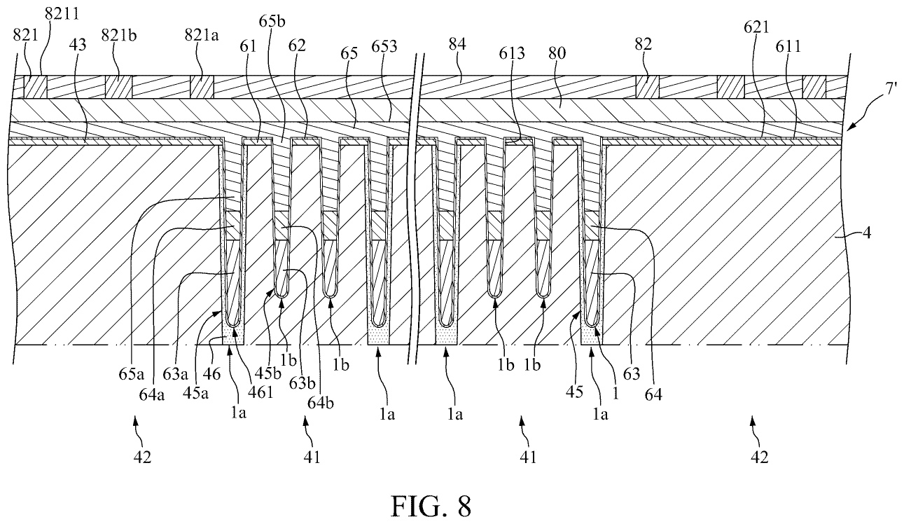

Referring to FIG. 8, the sacrificial layer 84 may be thinned to expose the top surfaces 8211 of the remaining portions 821 of the patterned photoresist layer 82 by, for example, etching. Meanwhile, a top surface 841 of the sacrificial layer 84 may be substantially coplanar with the top surfaces 8211 of the remaining portions 821 of the patterned photoresist layer 82.

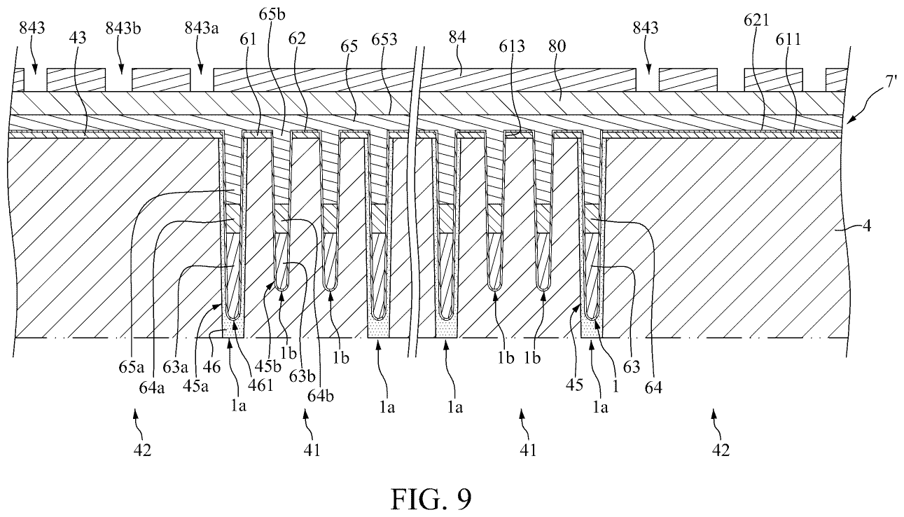

Referring to FIG. 9, the remaining portions 821 of the patterned photoresist layer 82 may be removed by, for example, stripping, to form a plurality of openings 843 in the sacrificial layer 84. A size and a position of each of the openings 843 of the sacrificial layer 84 may correspond to a size and a position of each of the remaining portions 821 of the patterned photoresist layer 82. In some embodiments, the openings 843 of the sacrificial layer 84 may include a first opening 843a corresponding to the first remaining portion 821a and a second opening 843b corresponding to the second remaining portion 821b. In addition, the openings 843 (including, for example, the first opening 843a and the second opening 843b) of the sacrificial layer 84 expose portions of the mask layer 80.

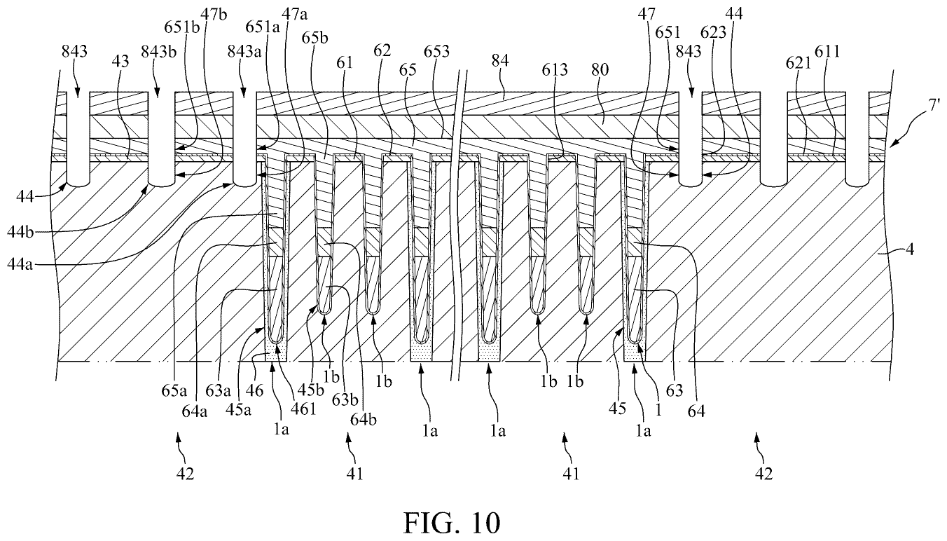

Referring to FIG. 10, portions of the word line nitride layer 65, portions of the isolation layer 62, portions of the cover layer 61 and portions of the periphery portion 42 may be removed concurrently so as to form a plurality of outer trenches 44 according to the openings 843 of the sacrificial layer 84. The outer trenches 44 may extend through the word line nitride layer 65, the isolation layer 62 and the cover layer 61, and extend into the periphery portion 42 of the substrate 4. In some embodiments, the outer trenches 44 may include a first outer trench 44a corresponding to the first opening 843a and a second outer trench 44b corresponding to the second opening 843b.

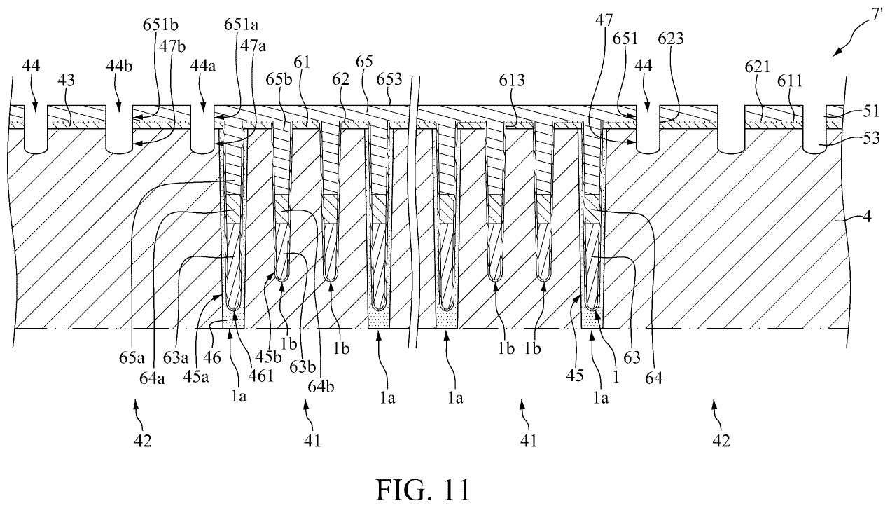

Referring to FIG. 11, the sacrificial layer 84 and the mask layer 80 may be removed. As shown in FIG. 11, the first outer trench 44a may be recessed into the first surface 653 of the word line nitride layer 65, and may include the first opening 651a of the word line nitride layer 65, the first recess 47a of the periphery portion 42, the opening 613 of the cover layer 61 and the opening 623 of the isolation layer 62. The second outer trench 44b may be recessed into the first surface 653 of the word line nitride layer 65, and may include the second opening 651b of the word line nitride layer 65, the second recess 47b of the periphery portion 42, the opening 613 of the cover layer 61 and the opening 623 of the isolation layer 62. Therefore, the recess 47 (including, for example, the first recess 47a and the second recess 47b) may be formed in the periphery portion 42 of the substrate 4.

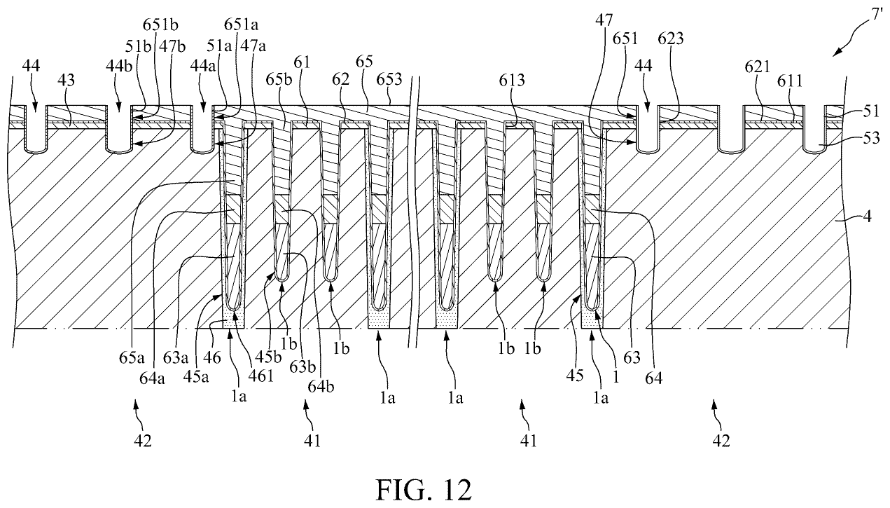

Referring to FIGS. 12 to 15, a recess transistor 5 may be formed in the outer trench 44 and in the recess 47 of the periphery portion 42 of the substrate 4. Referring to FIG. 12, an insulation layer 51 may be formed or disposed on a sidewall of the outer trench 44. Alternatively, the insulation layer 51 may be formed or disposed on a sidewall of the recess 47, on a sidewall of the opening 613 of the cover layer 61, on a sidewall of the opening 623 of the isolation layer 62 and on a sidewall of the opening 651 of the word line nitride layer 65.

In some embodiments, the insulation layer 51 may include a first insulation layer 51a and a second insulation layer 51b. The first insulation layer 51a may be disposed on a sidewall of the first outer trench 44a. That is, the first insulation layer 51a may be disposed on a sidewall of the first recess 47a of the periphery portion 42 and on a sidewall of the first opening 651a of the word line nitride layer 65. In addition, the second insulation layer 51b may be disposed on a sidewall of the second outer trench 44b. That is, the second insulation layer 51b may be disposed on a sidewall of the second recess 47b of the periphery portion 42 and on a sidewall of the second opening 651b of the word line nitride layer 65.

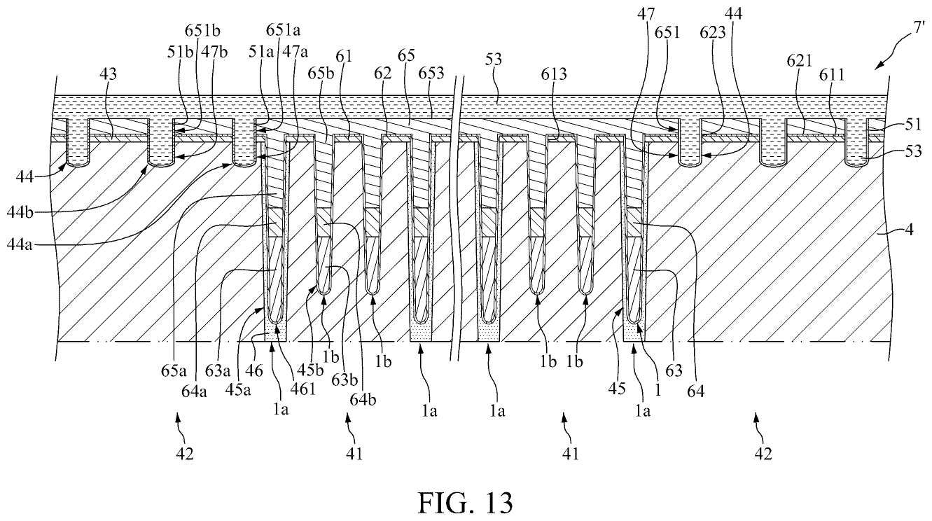

Referring to FIG. 13, a polysilicon layer 53 may be formed or disposed on the first surface 653 of the word line nitride layer 65 (i.e., on the first surface 43 (e.g., the top surface) of the substrate 4) and may fill the outer trench 44 by, for example, deposition. Thus, the polysilicon layer 53 may be formed or disposed on the insulation layer 51 in the outer trench 44 and in the recess 47 of the periphery portion 42.

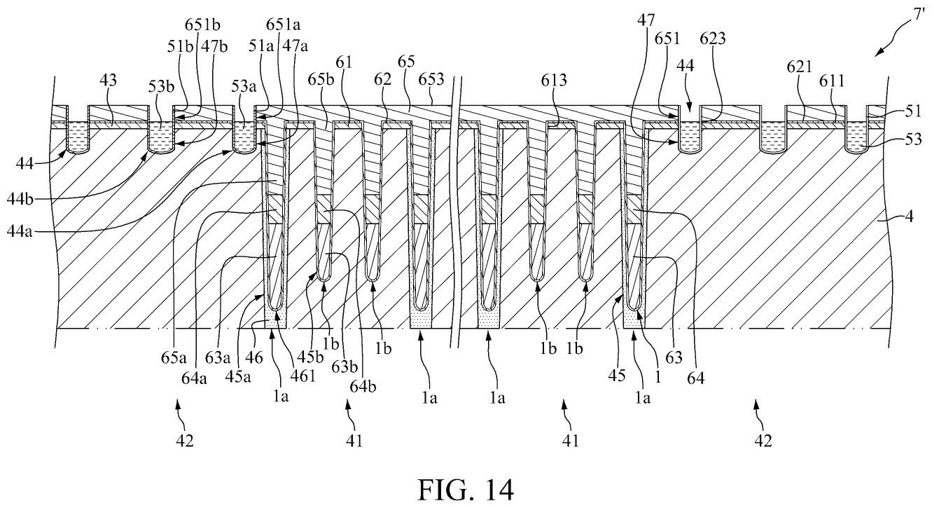

Referring to FIG. 14, the portion of the polysilicon layer 53 that is disposed on the first surface 653 of the word line nitride layer 65 (i.e., on the first surface 43 (e.g., the top surface) of the substrate 4) may be removed by, for example, etching. In some embodiments, an upper portion of the polysilicon layer 53 that is disposed in the outer trench 44 may be also removed. Thus, a top surface of the polysilicon layer 53 may be lower than the first surface 653 (e.g., the top surface) of the word line nitride layer 65. In some embodiments, the top surface of the polysilicon layer 53 may be lower than the first surface 621 (e.g., the top surface) of the isolation layer 62. The top surface of the polysilicon layer 53 may be higher than the first surface 43 (e.g., the top surface) of the substrate 4. The top surface of the polysilicon layer 53 may be higher than the first surface 611 (e.g., the top surface) of the cover layer 61.

Meanwhile, the polysilicon layer 53 may include a first polysilicon layer 53a and a second polysilicon layer 53b spaced apart from each other. The first polysilicon layer 53a may be disposed on the first insulation layer 51a in the first recess 47a of the periphery portion 42 of the substrate 4. Thus, the first insulation layer 51a may be disposed between the first polysilicon layer 53a and the periphery portion 42 of the substrate 4. The second polysilicon layer 53b may be disposed on the second insulation layer 51b in the second recess 47b of the periphery portion 42 of the substrate 4. Thus, the second insulation layer 51b may be disposed between the second polysilicon layer 53b and the periphery portion 42 of the substrate 4.

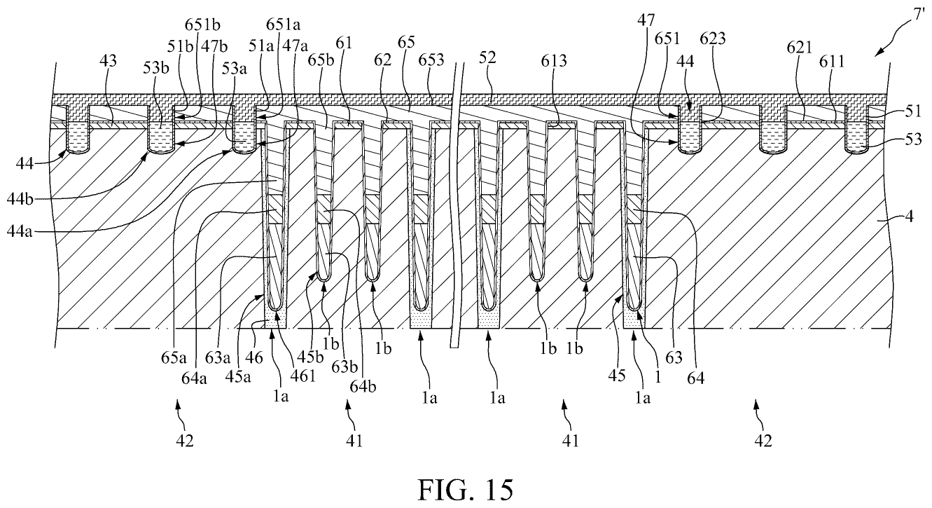

Referring to FIG. 15, a gate conductor 52 may be formed or disposed on the first surface 653 of the word line nitride layer 65 (i.e., on the first surface 43 (e.g., the top surface) of the substrate 4) and may fill the outer trench 44 by, for example, deposition. In some embodiments, the gate conductor 52 may be formed or disposed on the polysilicon layer 53 in the outer trench 44 and in the recess 47 of the periphery portion 42.

Referring to FIG. 1A, the portion of the gate conductor 52 that is disposed on the first surface 653 of the word line nitride layer 65 (i.e., on the first surface 43 (e.g., the top surface) of the substrate 4) may be removed by, for example, etching. In some embodiments, an upper portion of the gate conductor 52 that is disposed in the outer trench 44 may be also removed. Thus, a first surface 521 (e.g., a top surface) of the gate conductor 52 may be lower than the first surface 653 (e.g., the top surface) of the word line nitride layer 65. In some embodiments, the first surface 521 (e.g., the top surface) of the gate conductor 52 may be higher than the first surface 621 (e.g., the top surface) of the isolation layer 62. In addition, a bottom surface 522 of the gate conductor 52 may be higher than the first surface 43 (e.g., the top surface) of the substrate 4. In some embodiments, the bottom surface 522 of the gate conductor 52 may be higher than the first surface 611 (e.g., the top surface) of the cover layer 61. The bottom surface 522 of the gate conductor 52 may be lower than the first surface 621 (e.g., the top surface) of the isolation layer 62. The insulation layer 51, the polysilicon layer 53 and the gate conductor 52 may collectively form a recess transistor 5 disposed in an outer trench 44.

Meanwhile, the gate conductor 52 may include a first gate conductor 52a and a second gate conductor 52b spaced apart from each other. The first gate conductor 52a may be disposed on the first polysilicon layer 53a and the first insulation layer 51a. Thus, the first gate conductor 52a may be disposed in the first opening 651a of the word line nitride layer 65. The first insulation layer 51a may be disposed between the first gate conductor 52a and the word line nitride layer 65. The first insulation layer 51a, the first polysilicon layer 53a and the first gate conductor 52a may collectively form a first recess transistor 5a. The first recess transistor 5a may be disposed in the first outer trench 44a.

The second gate conductor 52b may be disposed on the second polysilicon layer 53b and the second insulation layer 51b. Thus, the second gate conductor 52b may be disposed in the second opening 651b of the word line nitride layer 65. The second insulation layer 51b may be disposed between the second gate conductor 52b and the word line nitride layer 65. The second insulation layer 51b, the second polysilicon layer 53b and the second gate conductor 52b may collectively form a second recess transistor 5b. The second recess transistor 5b may be disposed in the second outer trench 44b.

Therefore, the semiconductor structure 7 shown in FIG. 1A is obtained.

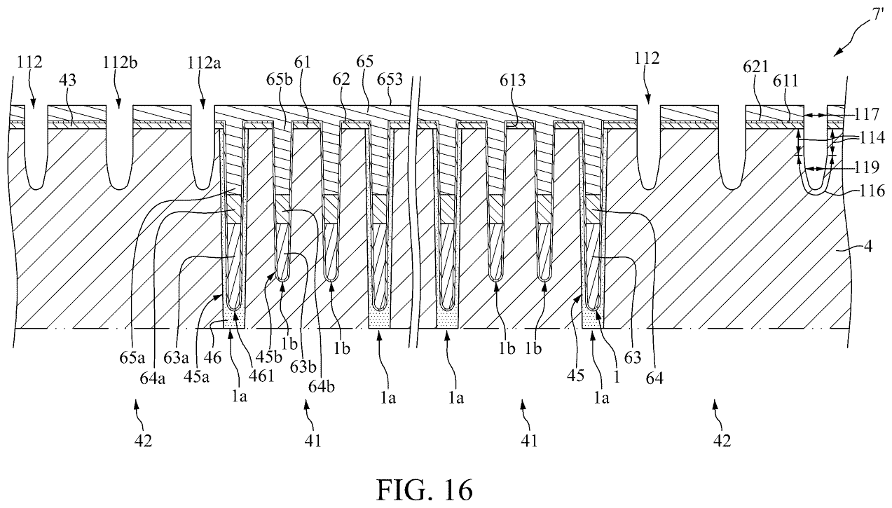

FIGS. 16 to 23 are cross-sectional views illustrating one or more stages of a method of manufacturing the semiconductor structure 7a in FIG. 1B in accordance with some embodiments of the present disclosure. As shown in FIGS. 16 to 23, a recess transistor 5′ may be formed in the periphery portion 42 of the substrate 4.

Referring to FIG. 16, at least one trench 112 (include a trench 112a and a trench 112b) may be formed by the method illustrated in FIGS. 3 to 11, and descriptions thereof are not repeated herein. As shown in FIG. 16, the trench 112 can include an upper segment 114, proximal to the word line nitride layer 65 and having a uniform width, and a lower segment 116, distal from the word line nitride layer 65 and having a tapering width. In other words, a sidewall of the upper segment 114 of the trench 112 is substantially a vertical plane, while a sidewall of the lower segment 116 of the trench 112 is a sloped surface, which transitions into the vertical plane. In some embodiments, the upper segment 114 of the trench 112 is wider than the bottom segment 116.

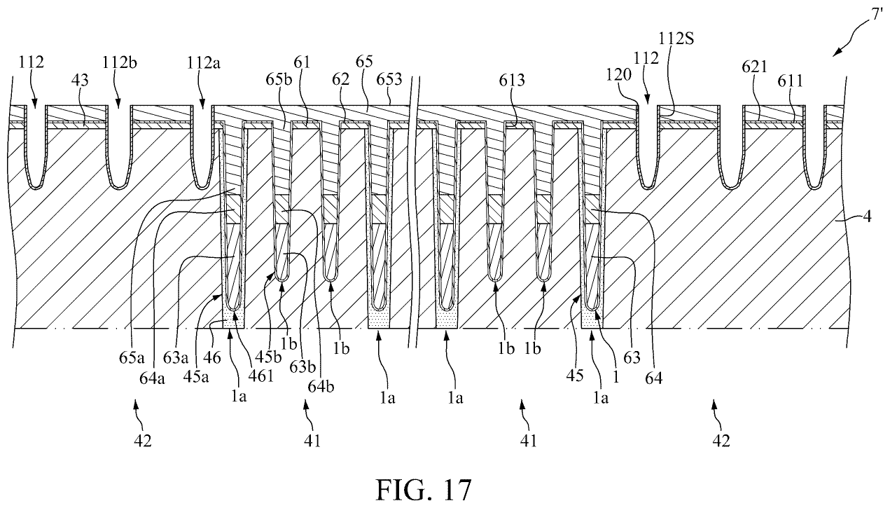

Referring to FIG. 17, a dielectric film 120 is formed in the trench 112. The dielectric film 120, having a substantially uniform thickness, covers a sidewall 112S of the trench 112, but does not fill the trench 112. In some embodiments, the dielectric film 120 and the isolation layer 62 can include a same material, but the present disclosure is not limited thereto. In some embodiments, the dielectric film 120 may be grown on the sidewall 112S of the trench 112 using a thermal oxidation process. In some embodiments, the dielectric film 120 includes oxide, nitride, oxynitride or high-k material and can be deposited using a CVD process, an ALD process, or the like. In some embodiments, the dielectric film 120 deposited on the first surface 653 (e.g., a top surface) of the word line nitride layer 65 may be removed using an etching process, for example, while the dielectric film 120 deposited on the sidewall 112S of the trench 112 is left in place.

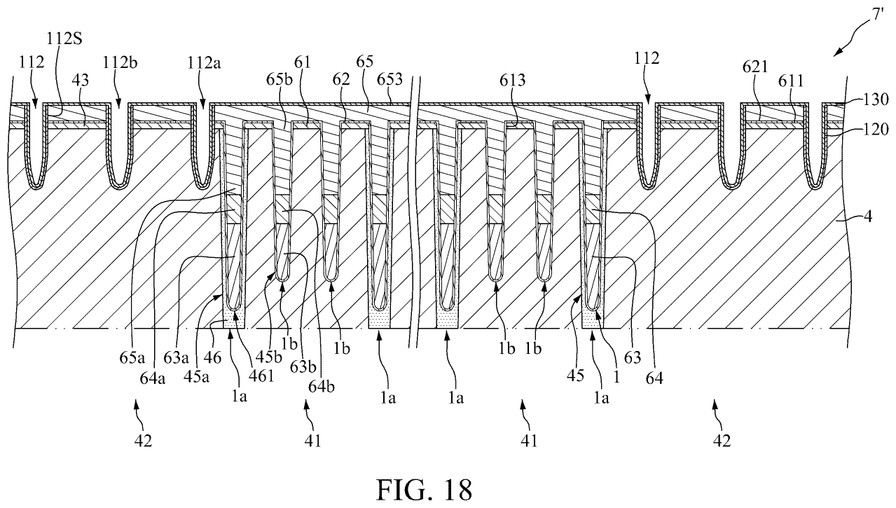

Referring to FIG. 18, a diffusion barrier layer 130 is optionally deposited on the dielectric film 120. The diffusion barrier layer 130 may further be deposited on the first surface 653 of the word line nitride layer 65. The diffusion barrier layer 130, having a substantially uniform thickness, covers the dielectric film 120, but does not fill the trench 112. In order to secure a step coverage, the diffusion barrier layer 130 can be formed using a PVD process or an ALD process, for example, wherein the diffusion barrier layer 130 deposited using the ALD process is highly uniform in thickness. In some embodiments, the diffusion barrier layer 130 may be a single-layered structure including refractory metals (such as tantalum and titanium), refractory metal nitrides, or refractory metal silicon nitrides. In alternative embodiments, the diffusion barrier layer 130 may comprise a multi-layered structure including one or more refractory metals, refractory metal nitrides, or refractory metal silicon nitrides.

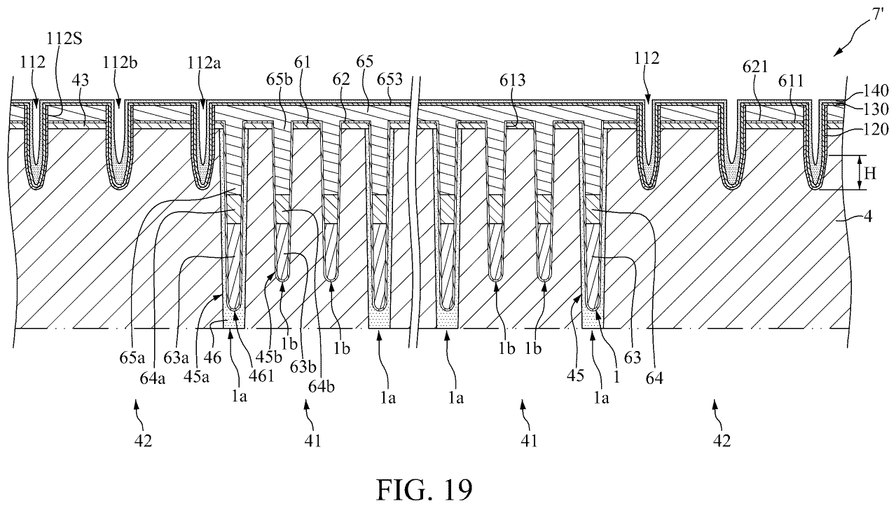

Referring to FIG. 19, a conductive material 140 is deposited to partially fill the trench 112. The conductive material 140 is conformally and uniformly deposited over the dielectric film 120. Due to a directionality in the deposition of the conductive material 140 toward a bottom of the trench 112, a rate of deposition of the conductive material 140 at the lower segment 116 (see FIG. 16) of the trench 112 is greater than a rate of deposition of the conductive material 140 at the upper segment 114 (see FIG. 16) of the trench 112. As a result, a thickness of the conductive material 140 at the lower segment 116 of the trench 112 is significantly greater than a thickness of the conductive material 140 at the upper segment 114 of the trench 112. In some embodiments, the deposition of the conductive material 140 stops when the conductive material 140 deposited in the trench 112 reaches a predetermined thickness H, which can mitigate a detrimental short-channel effect and improve device reliability. The conductive material 140 includes polysilicon or metal, such as tungsten, aluminum, copper, molybdenum, titanium, tantalum, ruthenium, or a combination thereof. The conductive material 140 may be formed using a CVD process, a PVD process, an ALD process or another suitable process.

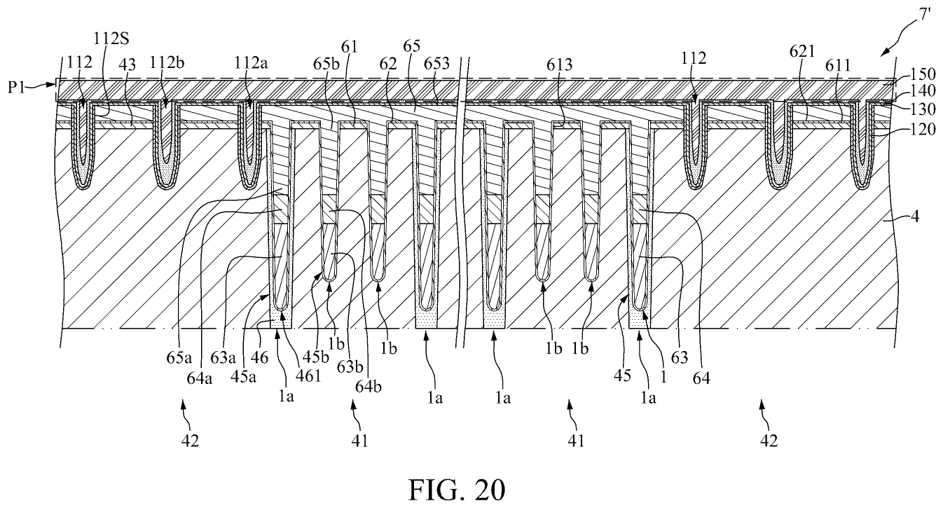

Referring to FIG. 20, an insulative material 150 is deposited to fill the trench 112. Consequently, the conductive material 140 is buried under the insulative material 150. The insulative material 150 has a sufficient thickness to fill the trench 112. The insulative material 150, including nitride, is formed using a (plasma) CVD process. In some embodiments, the insulative material 150 can include silicon nitride. In some embodiments, the insulative material 150 preferably includes a material having a high etching selectivity to the dielectric layer 120, the diffusion barrier layer 130 and the conductive material 140.

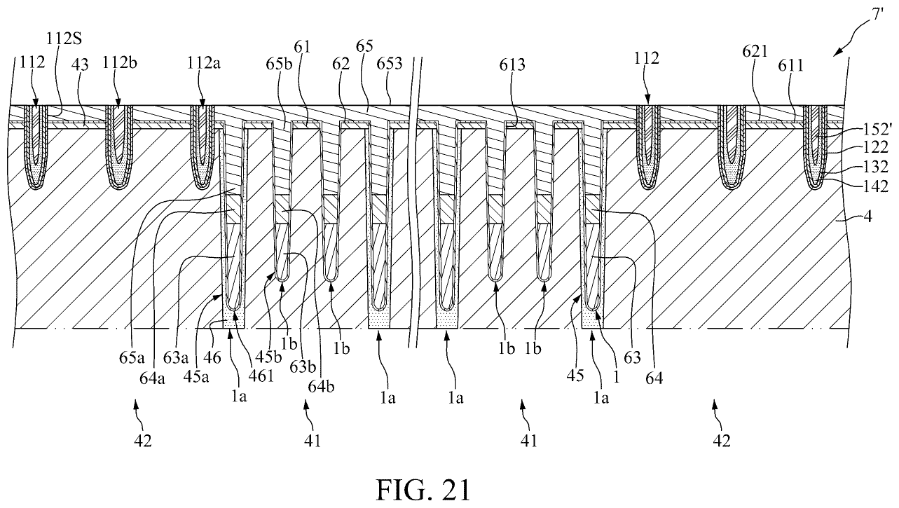

Referring to FIG. 21, portions of the diffusion barrier layer 130, the conductive material 140 and the insulative material 150 above the first surface 653 of the word line nitride layer 65 are removed to form a remaining dielectric film 122, a remaining diffusion barrier layer 132, a remaining conductive layer 142, and an insulative piece 152′. In some embodiments, the removal process may be performed by a polishing process and/or an etching process.

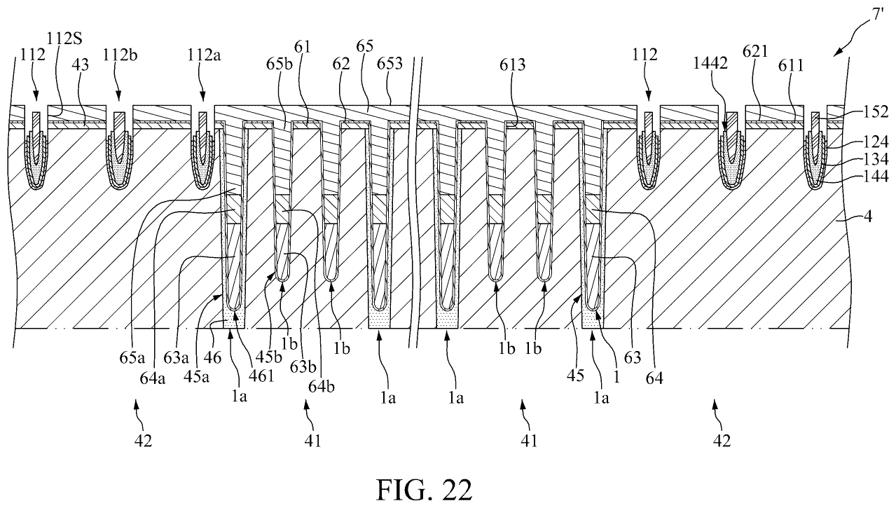

Referring to FIG. 22, the conductive layer 142 is further recessed to form a conductive layer 144 using one or more removal processes until a top surface of the conductive layer 142 is below the first surface 43 of the substrate 4. As shown in FIG. 22, the conductive layer 144 has a top surface 1442 lower than the first surface 43 of the substrate 4. In some embodiments, the remaining diffusion barrier layer 132 and the remaining dielectric film 122, shown in FIG. 21, can be sequentially recessed below the top surface 1442 of the conductive layer 144. Consequently, as shown in FIG. 22, a dielectric liner 124 and a diffusion barrier liner 134 between the substrate 4 and the conductive layer 144 are formed. In addition, after one or more removal processes, the insulative piece 152′ is turned into an insulative plug 152. It should be noted that a top surface of the insulative plug 152 is lower than a top surface of the insulative piece 152′.

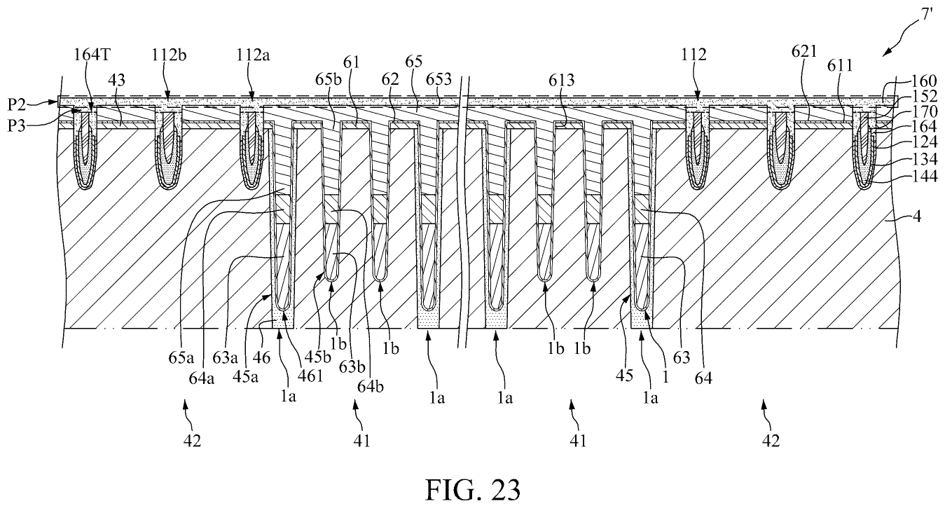

Referring to FIG. 23, a gate conductor material 160 is conformally deposited in the trench 112 and over the insulative plug 152. Next, a removal process is performed to remove a portion of the gate conductor material 160 in the trench 112 to form a gate conductor 164, wherein a top surface 164T of the gate conductor 164 and the top surface of the insulative plug 152 are coplanar. Because the insulative plug 152 narrows a width of the trench 112, one or more voids 170, holding an ambient gas (such as air), can be formed in the gate conductor 164 to reduce an effective dielectric constant of the gate conductor 164. As shown in FIG. 23, the void 170 is formed around the insulative plug 152. The gate conductor material 160 can be deposited using a CVD process. The removal of the portion of the gate conductor material 160 in the trench 112 can be performed using an anisotropic dry etching process. In some embodiments, the void 170 can be introduced in the gate conductor 164 by adjusting a deposition rate of the gate conductor material 160. In detail, the gate conductor material 160 cannot completely fill the trenches 112 when the gate conductor material 160 is deposited at a rapid rate. In some embodiments, the gate conductor material 160 may be, for example, a metal material, such as tungsten. Accordingly, as shown in FIG. 1B, a recess transistor 5′, comprising a recess transistor 5′a disposed in the trench 112a and a recess transistor 5′b disposed in the trench 112b, is formed.

Therefore, the semiconductor structure 7a shown in FIG. 1B is obtained.

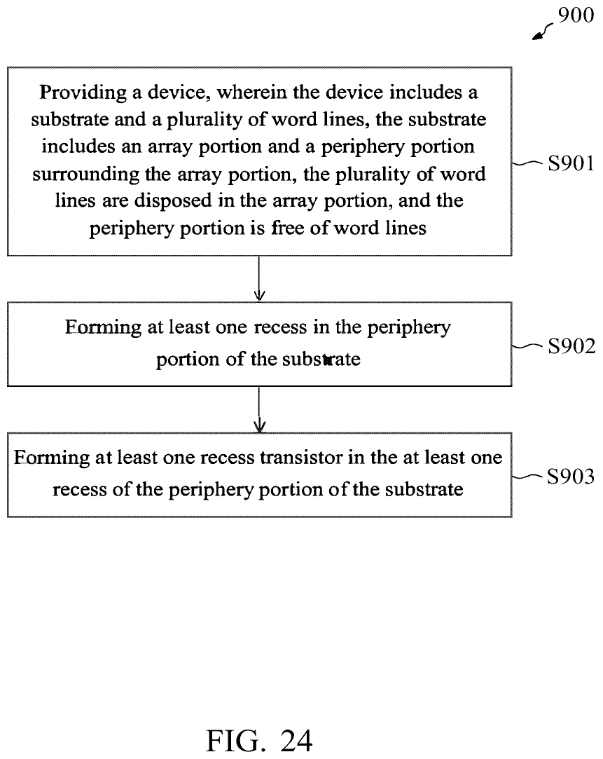

FIG. 24 is a flowchart of a method 900 of manufacturing a semiconductor structure according to some embodiments of the present disclosure.

In some embodiments, the method 900 can include a step S901, in which a device is provided, wherein the device includes a substrate and a plurality of word lines, the substrate includes an array portion and a periphery portion surrounding the array portion, the plurality of word lines are disposed in the array portion, and the periphery portion is free of word lines. In some embodiments, as shown in FIG. 3, a device 7′ is provided. The device 7′ includes a substrate 4 and a plurality of word lines 1. The substrate 4 includes an array portion 41 and a periphery portion 42 surrounding the array portion 41. The plurality of word lines 1 are disposed in the array portion 41. The periphery portion 42 is free of word lines.

In some embodiments, the method 900 can include a step S902, in which at least one recess is formed in the periphery portion of the substrate. In some embodiments, as shown in FIG. 11, the at least one recess 47 is formed in the periphery portion 42 of the substrate 4.

In some embodiments, the method 900 can include a step S903, in which at least one recess transistor is formed in the at least one recess of the periphery portion of the substrate. In some embodiments, as shown in FIG. 1, at least one recess transistor 5 is formed in the at least one recess 47 of the periphery portion 42 of the substrate 4.

Although the present disclosure and its advantages have been described in detail, it should be understood that various changes, substitutions and alterations can be made herein without departing from the spirit and scope of the disclosure as defined by the appended claims. In some embodiments, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor structure, comprising:
a device including a substrate and a plurality of word lines, wherein the substrate includes an array portion and a periphery portion surrounding the array portion, wherein the plurality of word lines are disposed in the array portion, wherein the periphery portion defines at least one trench; and
at least one recess transistor disposed in the at least one trench of the periphery portion of the substrate.

2. The semiconductor structure of claim 1, wherein the periphery portion is free of word lines.

3. The semiconductor structure of claim 1, wherein the at least one recess transistor includes a plurality of recess transistors with different widths.

4. The semiconductor structure of claim 1, wherein the at least one recess transistor comprises:
a conductive layer disposed in the trench;
an insulative plug disposed in the trench and extending into the conductive layer;
an insulation layer disposed between the substrate and the conductive layer and surrounding the conductive layer; and
a gate conductor conformally deposited in the trench and over the conductive layer, the insulative plug and the insulation layer.

5. The semiconductor structure of claim 4, further comprising a diffusion barrier liner disposed between the insulation layer and the conductive layer.

6. The semiconductor structure of claim 4, further comprising a void disposed in the gate conductor.

7. The semiconductor structure of claim 4, wherein the conductive layer includes a top surface lower than a first surface of the substrate.

8. The semiconductor structure of claim 4, wherein the conductive layer comprises tungsten, aluminum, copper, molybdenum, titanium, tantalum, ruthenium, or a combination thereof.

9. The semiconductor structure of claim 4, wherein the insulative plug comprises nitride and silicon nitride.

10. The semiconductor structure of claim 4, wherein the gate conductor comprises tungsten.

11. The semiconductor structure of claim 5, wherein the diffusion barrier liner comprises tantalum and titanium.

12. The semiconductor structure of claim 6, wherein the void is formed around the insulative plug and holds an ambient gas.

13. The semiconductor structure of claim 1, wherein the device further includes a word line nitride layer covering the array portion and the periphery portion of the substrate and extending into the plurality of word lines.

14. The semiconductor structure of claim 13, wherein a top surface of the gate conductor is lower than a top surface of the word line nitride layer.
